(19) United States
(12) Patent Application Publication
(10) Pub. No.: US 2025/0218899 A1
(43) Pub. Date: Jul. 3, 2025

(54) INTEGRATED CIRCUIT AND MANUFACTURING METHOD THEREOF

(71) Applicant: Taiwan Semiconductor Manufacturing Company, Ltd., Hsinchu (TW)

(72) Inventors: Isha Datye, Hsinchu (TW); Sam Vaziri, San Jose, CA (US); Xinyu BAO, Fremont, CA (US)

(73) Assignee: Taiwan Semiconductor Manufacturing Company, Ltd., Hsinchu (TW)

(21) Appl. No.: 18/399,748

(22) Filed: Dec. 29, 2023

(51) Int. Cl. H01L 23/48; H01L 21/768; H01L 23/00; H01L 23/373; H01L 25/065

(52) U.S. Cl. CPC H01L 23/481; H01L 21/76898; H01L 23/3732; H01L 24/32; H01L 25/0657; H01L 2224/32225; H01L 2225/06541; H01L 2924/1306

(57) ABSTRACT

An integrated circuit includes a semiconductor substrate and an interconnect structure. The interconnect structure is disposed on the semiconductor substrate. The interconnect structure includes a signal transmission structure and a heat dissipation structure. The heat dissipation structure is disposed on the signal transmission structure and includes composite dielectric layers and first conductive features. Each of the composite dielectric layers includes a seed layer and a heat dissipation layer disposed on the seed layer. The first conductive features are embedded in the composite dielectric layers.

### BACKGROUND

The semiconductor integrated circuit (IC) industry has experienced a fast-paced growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1L are schematic cross-sectional views illustrating a manufacturing process of an integrated circuit in accordance with some embodiments of the disclosure.

FIG. 2A to FIG. 2E are schematic cross-sectional views illustrating a manufacturing process of an integrated circuit in accordance with some alternative embodiments of the disclosure.

FIG. 3 is a schematic cross-sectional view of an integrated circuit in accordance with some alternative embodiments of the disclosure.

FIG. 4A to FIG. 4E are schematic cross-sectional views illustrating a manufacturing process of an integrated circuit in accordance with some alternative embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

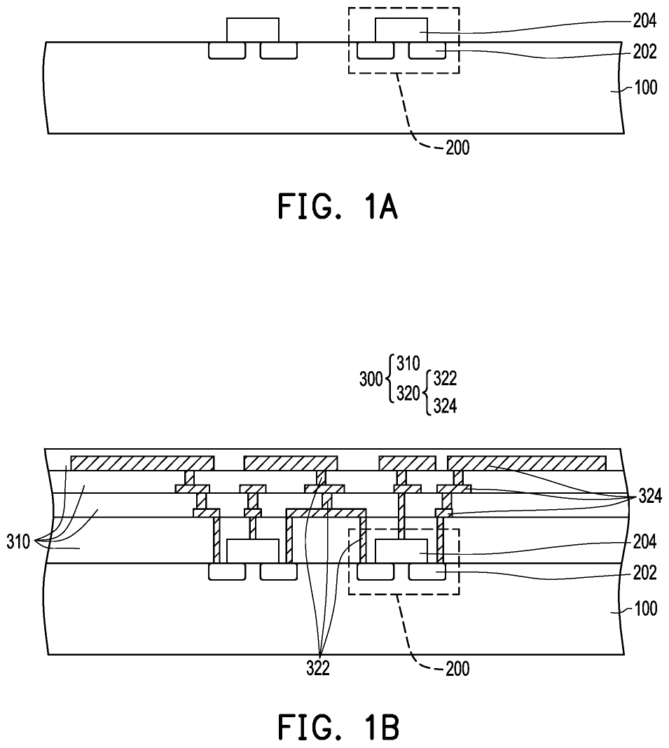

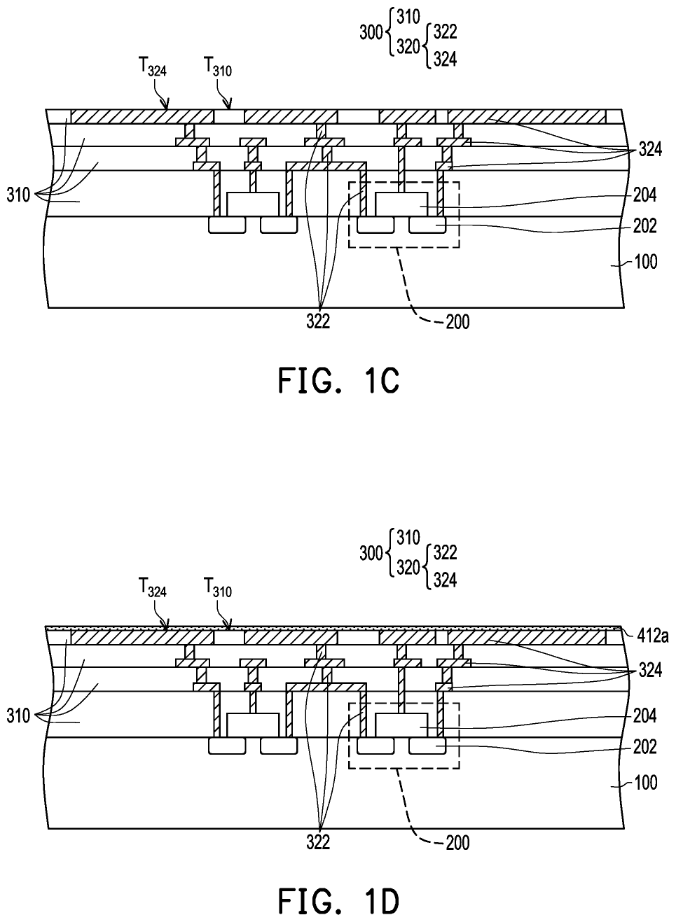

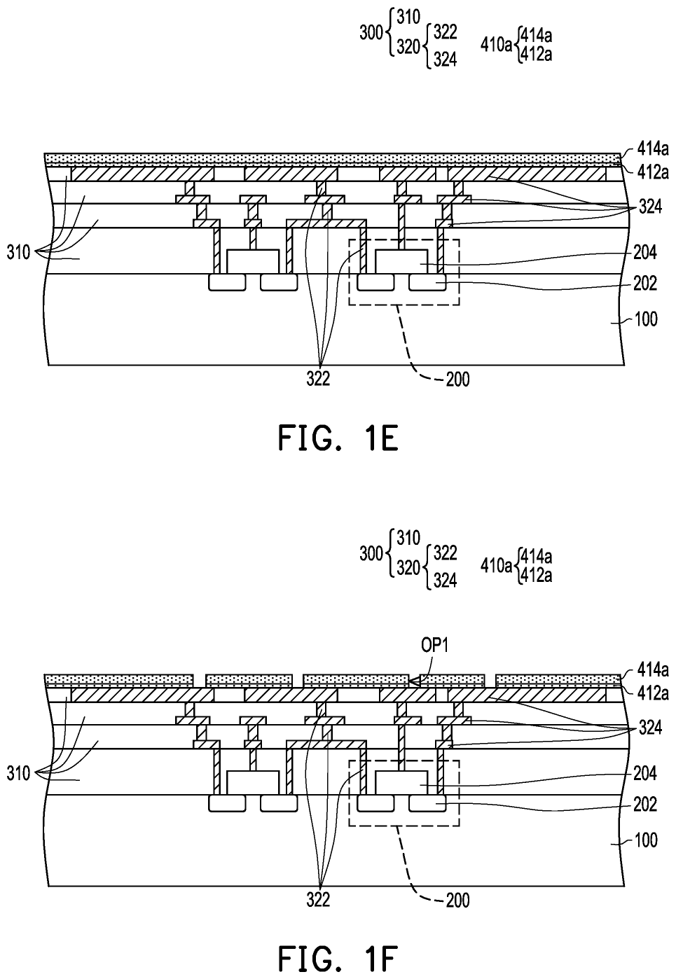

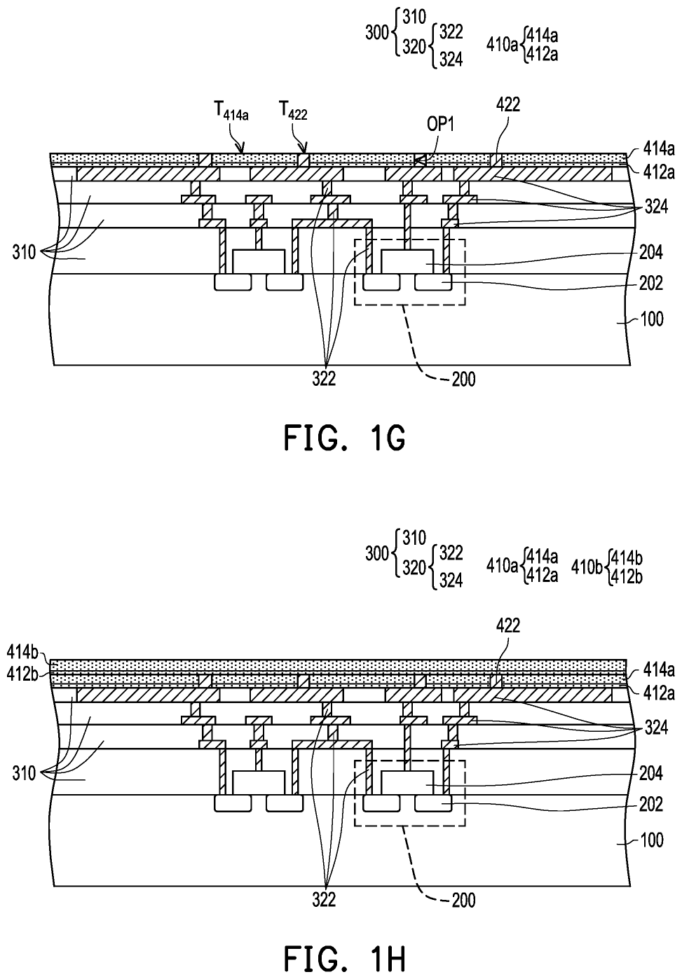

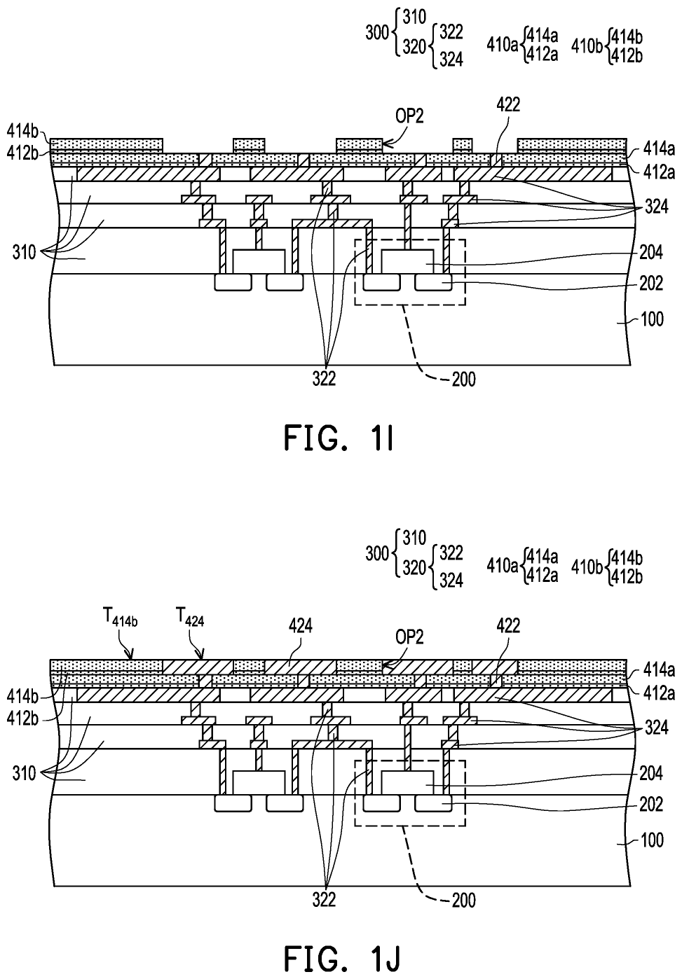

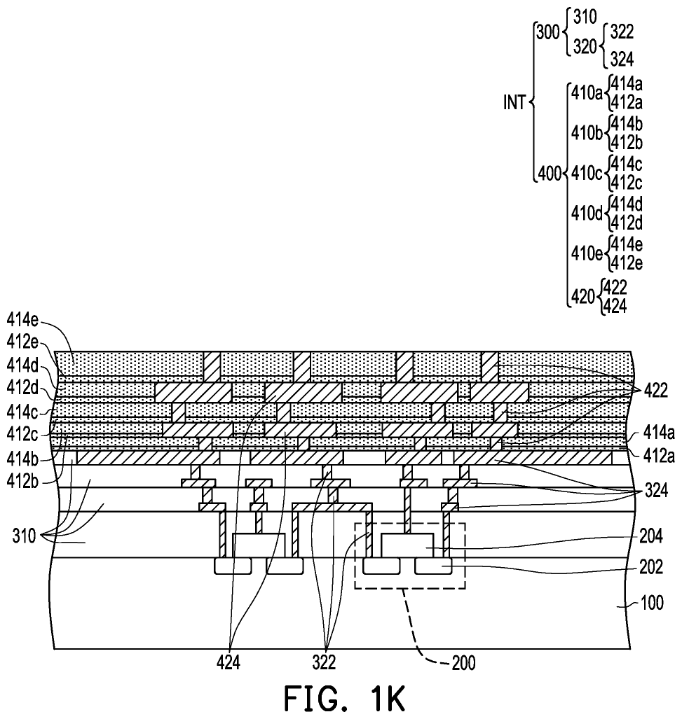

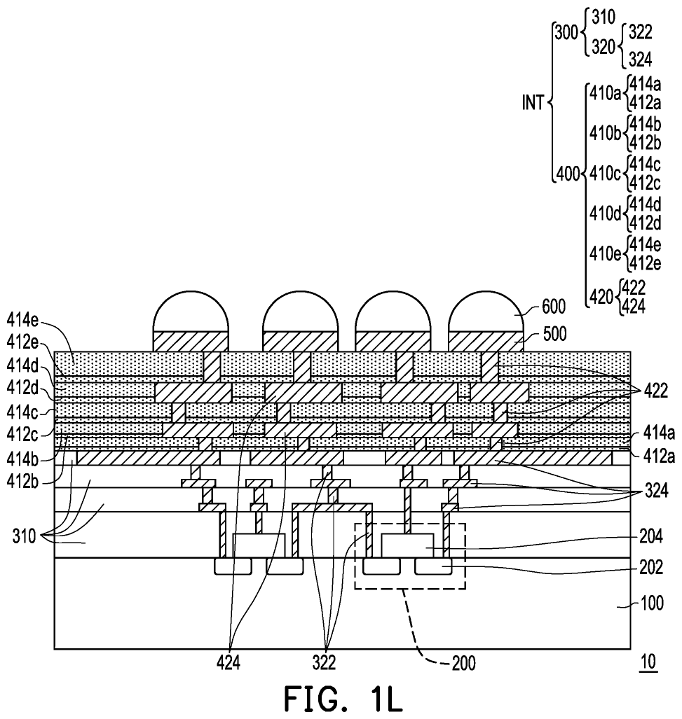

FIG. 1A to FIG. 1L are schematic cross-sectional views illustrating a manufacturing process of an integrated circuit 10 in accordance with some embodiments of the disclosure. Referring to FIG. 1A, a semiconductor substrate 100 is provided. In some embodiments, the semiconductor substrate 100 is made of elemental semiconductor materials, such as crystalline silicon, diamond, or germanium; compound semiconductor materials, such as silicon carbide, gallium arsenic, indium arsenide, or indium phosphide; or alloy semiconductor materials, such as silicon germanium, silicon germanium carbide, gallium arsenic phosphide, or gallium indium phosphide. The semiconductor substrate 100 may be a bulk silicon substrate, a silicon-on-insulator (SOI) substrate, or a germanium-on-insulator (GOI) substrate.

As illustrated in FIG. 1A, a plurality of transistors 200 is formed on the semiconductor substrate 100. In some embodiments, each transistor 200 includes source/drain regions 202 and a gate electrode 204. In some embodiments, each transistor 200 further includes a channel region (not shown) under the gate electrode 204. In some embodiments, the channel region is also located between the source/drain regions 202 to serve as a path for electron to travel when the transistor 200 is turned on.

In some embodiments, the semiconductor substrate 100 includes various doped regions depending on circuit requirements (e.g., p-type semiconductor substrate or n-type semiconductor substrate). In some embodiments, the doped regions are doped with p-type or n-type dopants. For example, the doped regions may be doped with p-type dopants, such as boron or BF₂; n-type dopants, such as phosphorus or arsenic; and/or combinations thereof. In some embodiments, these doped regions serve as the source/drain regions 202 of the transistors 200. Depending on the types of the dopants in the doped regions, the transistors 200 may be referred to as n-type transistors or p-type transistors.

In some embodiments, the gate electrode 204 includes copper, titanium, tantalum, tungsten, aluminum, zirconium, hafnium, cobalt, titanium aluminum, tantalum aluminum, tungsten aluminum, zirconium aluminum, hafnium aluminum, titanium nitride, any other suitable metal-containing material, or a combination thereof. In some embodiments, the gate electrode 204 also includes materials to fine-tune the corresponding work function. For example, the gate electrode 204 may also include p-type work function materials such as Ru, Mo, WN, ZrSi₂, MoSi₂, TaSi₂, NiSi₂, or combinations thereof, or n-type work function materials such as Ag, TaCN, Mn, or combinations thereof.

As illustrated in FIG. 1A, the source/drain regions 202 are embedded in the semiconductor substrate 100 and the gate electrode 204 is located above the semiconductor substrate 100. However, the disclosure is not limited thereto. In some alternative embodiments, the source/drain regions 202 and the gate electrode 204 are both located above the semiconductor substrate 100. In some embodiments, the transistors 200 may be separated by a shallow trench isolation (STI; not shown) located between two adjacent transistors 200. In some embodiments, the transistors 200 are formed using suitable Front-end-of-line (FEOL) process.

Referring to FIG. 1B, a signal transmission structure 300 is formed on the semiconductor substrate 100 and the transistors 200. In some embodiments, the signal transmission structure 300 includes a plurality of dielectric layers 310 and a plurality of conductive features 320. In some embodiments, the dielectric layers 310 are stacked on one another. For example, the adjacent dielectric layers 310 are in physical contact with each other. In some embodiments, a material of the dielectric layers 310 includes polyimide, epoxy resin, acrylic resin, phenol resin, benzocyclobutene (BCB), polybenzooxazole (PBO), or any other suitable polymer-based dielectric material. Alternatively, the dielectric layers 310 may be formed of oxides or nitrides, such as silicon oxide, silicon nitride, hafnium oxide, hafnium zirconium oxide, or the like. In some embodiments, different dielectric layers 310 are formed by the same material. However, the disclosure is not limited thereto. In some alternative embodiments, different dielectric layers 310 may be formed by different materials. The dielectric layers 310 may be formed by suitable fabrication techniques, such as spin-on coating, chemical vapor deposition (CVD), plasma-enhanced chemical vapor deposition (PECVD), or the like. In some embodiments, a number of the dielectric layers 310 is four or more.

In some embodiments, the conductive features 320 include a plurality of conductive vias 322 and a plurality of conductive patterns 324. As illustrated in FIG. 1B, the conductive features 320 are embedded in the dielectric layers 310. That is, the conductive vias 322 and the conductive patterns 324 are embedded in the dielectric layers 310. For example, the dielectric layers 310 laterally encapsulate the conductive vias 322 and the conductive patterns 324. In some embodiments, the conductive patterns 324 extend horizontally. Meanwhile, the conductive vias 322 extend vertically to connect the conductive patterns 324 located at different level heights. In other words, the conductive patterns 324 are electrically connected to one another through the conductive vias 322. In some embodiments, the bottommost conductive vias 322 are connected to the transistors 200. For example, the bottommost conductive vias 322 are connected to the source/drain regions 202 and the gate electrodes 204 of the transistors 200. In other words, the bottommost conductive vias 322 establish electrical connection between the transistors 200 and the conductive patterns 324. That is, the conductive features 320 are electrically connected to the transistors 200. In some embodiments, the bottommost conductive vias 322 may be referred to as “contact structures” of the transistors 200.

In some embodiments, a material of the conductive patterns 324 and the conductive vias 322 includes aluminum, titanium, copper, nickel, tungsten, or alloys thereof. The conductive patterns 324 and the conductive vias 322 may be formed by electroplating, deposition, and/or photolithography and etching. In some embodiments, the conductive patterns 324 and the underlying conductive vias 322 are separately formed. However, the disclosure is not limited thereto. In some alternative embodiments, the conductive patterns 324 and the underlying conductive vias 322 may be formed simultaneously. As illustrated in FIG. 1B, the conductive vias 322 and the underlying conductive patterns 324 are embedded in the same dielectric layer 310. In other words, a top surface of each conductive via 322 is coplanar with a top surface of the corresponding dielectric layer 310. Meanwhile, a top surface of each conductive pattern 324 is located at a level height lower than that of the top surface of the corresponding dielectric layer 310. That is, the top surfaces of the conductive patterns 324 are covered by the dielectric layers 310.

Referring to FIG. 1B and FIG. 1C, a planarization process is performed on the topmost dielectric layer 310 until the topmost conductive patterns 324 are revealed. That is, after the planarization process, top surfaces T₃₂₄ of the topmost conductive patterns 324 are coplanar with a top surface T₃₁₀ of the topmost dielectric layer 310. In some embodiments, the planarization process reduces a surface roughness of the top surfaces T₃₂₄ of the topmost conductive patterns 324 and a surface roughness of the top surface T₃₁₀ of the topmost dielectric layer 310 to less than 1 nm. In some embodiments, the planarization process includes a mechanical grinding process, a chemical mechanical polishing (CMP) process, or the like.

Referring to FIG. 1D, a seed layer 412a is deposited on the signal transmission structure 300. For example, the seed layer 412a is formed on the topmost dielectric layer 310 and the topmost conductive patterns 324. As illustrated in FIG. 1D, the seed layer 412a is in physical contact with the top surface T₃₁₀ of the topmost dielectric layer 310 and the top surfaces T₃₂₄ of the topmost conductive patterns 324. As mentioned above, the surface roughness of the top surfaces T₃₂₄ of the topmost conductive patterns 324 and the surface roughness of the top surface T₃₁₀ of the topmost dielectric layer 310 are less than 1 nm. As such, the seed layer 412a is deposited on a substantially flat surface. In some embodiments, the seed layer 412a is made of a dielectric material. However, a material of the seed layer 412a is different from the material of the dielectric layers 310. In some embodiments, the seed layer 412a is made of a material that is lattice-matched to diamond. For example, the material of the seed layer 412a includes cubic boron nitride (c-BN) or the like. In some embodiments, the seed layer 412a is deposited on the signal transmission structure 300 through CVD, physical vapor deposition (PVD), or the like. In some embodiments, the seed layer 412a is formed to have a thickness ranging between about 10 nm to about 50 nm. As mentioned above, the material of the seed layer 412a is different from the material of the dielectric layers 310. As such, an interface exits between the seed layer 412a and the topmost dielectric layer 310, as shown in FIG. 1D.

Referring to FIG. 1E, after the seed layer 412a is formed on the signal transmission structure 300, a diamond layer 414a is grown on the seed layer 412a. In some embodiments, a material of the diamond layer 414a is different from the material of the dielectric layers 310. For example, the material of the diamond layer 414a includes diamond. In some embodiments, the diamond layer 414a is formed on the seed layer 412a through CVD, microwave plasma chemical vapor deposition (MPCVD), or the like. In some embodiments, the process temperature for growing the diamond layer 414a is 400° C. or lower. In some embodiments, since the lattice of the material of the seed layer 412a (i.e., cubic boron nitride) matches with the lattice of the material of the diamond layer 414a (i.e., diamond), the diamond layer 414a may be effectively epitaxial grown on the seed layer 412a at low temperature. In some embodiments, the diamond layer 414a is formed to have a thickness ranging between about 100 nm to about 5,000 nm. In some embodiments, after the diamond layer 414a is formed on the seed layer 412a, a planarization process is performed on the diamond layer 414a. In some embodiments, the planarization process includes a mechanical grinding process, a CMP process, or the like. After the planarization process, the diamond layer 414a has a substantially flat top surface. It should be noted that the planarization process herein may be optional and may be omitted in certain embodiments.

In some embodiments, since both of the seed layer 412a and the diamond layer 414a are made of dielectric materials, the seed layer 412a and the diamond layer 414a may be collectively referred to as a composite dielectric layer 410a. That is, the composite dielectric layer 410a is grown on the topmost dielectric layer 310 and the topmost conductive patterns 324.

By performing the steps shown in FIG. 1D to FIG. 1E, the composite dielectric layer 410a can be easily grown on the signal transmission structure 300. In some embodiments, the signal transmission structure 300 and the composite dielectric layer 410a are considered as formed during back-end-of-line (BEOL) process. Conventionally, the thermal budget (i.e., the process temperature window) for BEOL process is low. As mentioned above, by first depositing the seed layer 412a on the signal transmission structure 300 and subsequently growing the diamond layer 414a on the seed layer 412a, the process temperature for forming the composite dielectric layer 410a can be low (i.e., 400° C. or lower), which falls within the thermal budget for BEOL process. In other words, with the adoption of the seed layer 412a, the diamond layer 414a can be integrated into the subsequently formed integrated circuit 10 while being compatible with the BEOL thermal budget.

Referring to FIG. 1E and FIG. 1F, the seed layer 412a and the diamond layer 414a are patterned to form a plurality of openings OP1 in the seed layer 412a and the diamond layer 414a. That is, the openings OP1 are formed in the composite dielectric layer 410a. In some embodiments, the openings OP1 penetrate through the composite dielectric layer 410a. For example, the openings OP1 penetrate through the seed layer 412a and the diamond layer 414a to partially expose the underlying conductive patterns 324. That is, the openings OP1 partially expose the topmost conductive patterns 324. In some embodiments, the patterning process of the seed layer 412a and the diamond layer 414a includes a photolithography process and an etching process. The etching process includes a dry etching process. For example, the seed layer 412a and the diamond layer 414a may be patterned through reactive ion etch (RIE), inductively coupled plasma (ICP) etch, electron cyclotron resonance (ECR) etch, neutral beam etch (NBE), or the like. In some embodiments, oxygen may be used as an etching gas during the dry etching process.

Referring to FIG. 1G, a conductive material (not shown) is deposited into the openings OP1 to form a plurality of conductive vias 422. For example, the conductive material is conformally formed on the composite dielectric layer 410a. In some embodiments, the conductive material also fills up the openings OP1. In some embodiments, the conductive material includes aluminum, titanium, copper, nickel, tungsten, or alloys thereof. In some embodiments, the conductive material is deposited onto the composite dielectric layer 410a and into the openings OP1 through PVD, ion beam deposition (IBD), CVD, ALD, molecular beam epitaxy (MBE), electro-chemical plating (ECP), electroless deposition (ELD), or the like. Thereafter, a planarization process is performed on the conductive material until the diamond layer 414a is revealed, so as to form the conductive vias 422 in the openings OP1. In some embodiments, the planarization process includes a mechanical grinding process, a CMP process, or the like. After the planarization process, top surfaces T₄₂₂ of the conductive vias 422 are coplanar with a top surface T₄₁₄ₐ of the diamond layer 414a. In other words, the composite dielectric layer 410a laterally encapsulates the conductive vias 422 and exposes the top surfaces T₄₂₂ of the conductive vias 422. In some embodiments, the planarization process reduces a surface roughness of the top surfaces T₄₂₂ of the conductive vias 422 and a surface roughness of the top surface T₄₁₄ₐ of the diamond layer 414a to less than 1 nm.

Referring to FIG. 1H, a composite dielectric layer 410b is formed on the composite dielectric layer 410a and the conductive vias 422. In some embodiments, the composite dielectric layer 410b includes a seed layer 412b and a diamond layer 414b disposed on the seed layer 412b. The seed layer 412b and the diamond layer 414b in FIG. 1H are respectively similar to the seed layer 412a and the diamond layer 414a in FIG. 1E, so the detailed descriptions thereof are omitted herein. In some embodiments, the composite dielectric layer 410b may be formed on the composite dielectric layer 410a and the conductive vias 422 through steps similar to the steps shown in FIG. 1D to FIG. 1E.

Referring to FIG. 1H and FIG. 1I, the seed layer 412b and the diamond layer 414b are patterned to form a plurality of openings OP2 in the seed layer 412b and the diamond layer 414b. That is, the openings OP2 are formed in the composite dielectric layer 410b. In some embodiments, the openings OP2 penetrate through the composite dielectric layer 410b. For example, the openings OP2 penetrate through the seed layer 412b and the diamond layer 414b to expose the underlying conductive vias 422. In some embodiments, the openings OP2 also partially exposes the underlying composite dielectric layer 410a. In some embodiments, the patterning process of the seed layer 412b and the diamond layer 414b includes a photolithography process and an etching process. The etching process includes a dry etching process. For example, the seed layer 412b and the diamond layer 414b may be patterned through RIE, ICP etch, ECR etch, NBE, or the like. In some embodiments, oxygen may be used as an etching gas during the dry etching process.

Referring to FIG. 1J, a conductive material (not shown) is deposited into the openings OP2 to form a plurality of conductive patterns 424. For example, the conductive material is conformally formed on the composite dielectric layer 410b. In some embodiments, the conductive material also fills up the openings OP2. In some embodiments, the conductive material includes aluminum, titanium, copper, nickel, tungsten, or alloys thereof. In some embodiments, the conductive material is deposited onto the composite dielectric layer 410b and into the openings OP2 through PVD, IBD, CVD, ALD, MBE, ECP, ELD, or the like. Thereafter, a planarization process is performed on the conductive material until the diamond layer 414b is revealed, so as to form the conductive patterns 424 in the openings OP2. In some embodiments, the planarization process includes a mechanical grinding process, a CMP process, or the like. After the planarization process, top surfaces T₄₂₄ of the conductive patterns 424 are coplanar with a top surface T_{414b} of the diamond layer 414b. In other words, the composite dielectric layer 410b laterally encapsulates the conductive patterns 424 and exposes the top surfaces T₄₂₄ of the conductive patterns 424. In some embodiments, the planarization process reduces a surface roughness of the top surfaces T₄₂₄ of the conductive patterns 424 and a surface roughness of the top surface T_{414b} of the diamond layer 414b to less than 1 nm.

As illustrated in FIG. 1J, each of the conductive patterns 424 penetrates through one of the composite dielectric layers (i.e., the composite dielectric layer 410b) while each of the conductive vias 422 penetrates through another one of the composite dielectric layers (i.e., the composite dielectric layer 410a). For example, each of the conductive patterns 424 penetrates through one of the seed layers (i.e., the seed layer 412b) and one of the diamond layers (i.e., the diamond layer 414b) while each of the conductive vias 422 penetrates through another one of the seed layers (i.e., the seed layer 412a) and another one of the diamond layers (i.e., the diamond layer 414a).

Referring to FIG. 1K, the steps shown in FIG. 1D to FIG. 1J are repeated couple times to form a heat dissipation structure 400 on top of the signal transmission structure 300. In some embodiments, the heat dissipation structure 400 includes a plurality of composite dielectric layers 410a, 410b, 410c, 410d, 410e and a plurality of conductive features 420. In some embodiments, the composite dielectric layers 410a, 410b, 410c, 410d, and 410e are stacked on one another. For example, the adjacent composite dielectric layers 410a, 410b, 410c, 410d, and 410e are in physical contact with each other. In some embodiments, the composite dielectric layer 410c includes a seed layer 412c and a diamond layer 414c disposed on the seed layer 412c, the composite dielectric layer 410d includes a seed layer 412d and a diamond layer 414d disposed on the seed layer 412d, and the composite dielectric layer 410e includes a seed layer 412e and a diamond layer 414e disposed on the seed layer 412e. The seed layers 412c, 412d, 412e and the diamond layers 414c, 414d, 414e in FIG. 1K are respectively similar to the seed layer 412a and the diamond layer 414a in FIG. 1E, so the detailed descriptions thereof are omitted herein. As illustrated in FIG. 1K, the seed layers 412a, 412b, 412c, 412d, 412e and the diamond layers 414a, 414b, 414c, 414d, 414e are alternately stacked on one another above the dielectric layers 310.

In some embodiments, the conductive features 420 include the conductive vias 422 and the conductive patterns 424. In some embodiments, the conductive features 420 are embedded in the composite dielectric layers 410a, 410b, 410c, 410d, and 410e. As illustrated in FIG. 1K, the conductive vias 422 are embedded in the composite dielectric layers 410a, 410c, and 410e. On the other hand, the conductive patterns 424 are embedded in the composite dielectric layers 410b and 410d. For example, the conductive vias 422 are embedded in the seed layers 412a, 412c, 412e and the diamond layers 414a, 414c, 414e while the conductive patterns 424 are embedded in the seed layers 412b, 412d and the diamond layers 414b, 414d. In some embodiments, the conductive patterns 424 extend horizontally.

Meanwhile, the conductive vias 422 extend vertically to connect the conductive patterns 424 located at different level heights. In other words, the conductive patterns 424 are electrically connected to one another through the conductive vias 422. In some embodiments, the conductive vias 422 and the conductive patterns 424 penetrate through different composite dielectric layers 410a, 410b, 410c, 410d, and 401e. For example, the conductive vias 422 penetrate through the corresponding composite dielectric layers 410a, 410c, and 410e while the conductive patterns 424 penetrate through the corresponding composite dielectric layers 410b and 410d. As illustrated in FIG. 1K, a top surface of each of the diamond layers 414a, 414b, 414c, 414d, and 414e is coplanar with a top surface of the corresponding conductive feature 420. Meanwhile, a top surface of each of the seed layers 412a, 412b, 412c, 412d, and 412e is located at a level height lower than that of the top surface of the corresponding conductive feature 420.

In some embodiments, since the diamond layers 414a, 414b, 414c, 414d, and 414e are made of diamond, a thermal conductivity of the diamond layers 414a, 414b, 414c, 414d, and 414e are high. For example, the thermal conductivity of the diamond layers 414a, 414b, 414c, 414d, and 414e is 200 W/(m·K) or higher. As such, heat generated during the operation of the subsequently formed integrated circuit 10 may be sufficiently dissipated by the diamond layers 414a, 414b, 414c, 414d, and 414e. Therefore, in some embodiments, the diamond layers 414a, 414b, 414c, 414d, and 414e may be referred to as heat dissipation layers. With the integration of these heat dissipation layers (i.e., the diamond layers 414a, 414b, 414c, 414d, and 414e), the performance and the lifetime of the subsequently formed integrated circuit 10 may be sufficiently improved.

In some embodiments, the heat dissipation structure 400 is in physical contact with the signal transmission structure 300. For example, the topmost dielectric layer 310 of the signal transmission structure 300 is in physical contact with the bottommost seed layer (i.e., the seed layer 412a) of the heat dissipation structure 400. Meanwhile, the bottommost conductive features 420 (i.e., the bottommost conductive vias 422) of the heat dissipation structure 400 are in physical contact with the topmost conductive features 320 (i.e., the topmost conductive patterns 324) of the signal transmission structure 300. In other words, the conductive features 420 of the heat dissipation structure 400 are electrically connected to the conductive features 320 of the signal transmission structure 300. For example, the conductive vias 322, the conductive patterns 324, the conductive vias 422, and the conductive patterns 424 are electrically connected to one another. In some embodiments, the conductive features 420 are electrically connected to the transistors 200 through the conductive features 320.

Since the conductive features 420 of the heat dissipation structure 400 are electrically connected to the conductive features 320 of the signal transmission structure 300, other than dissipating heat, the heat dissipation structure 400 also serves the function of signal transmission.

In some embodiments, the signal transmission structure 300 and the heat dissipation structure 400 are collectively referred to as an interconnect structure INT. That is, the interconnect structure INT is disposed on the semiconductor substrate 100. As illustrated in FIG. 1K, the transistors 200 are partially embedded in the interconnect structure INT. For example, the gate electrodes 204 of the transistors 200 are embedded in the signal transmission structure 300 of the interconnect structure INT.

It should be noted that the number of the composite dielectric layers 410a, 410b, 410c, 410d, 410e, the number of the conductive vias 422, and the number of the conductive patterns 424 illustrated in FIG. 1K are merely for illustrative purposes, and the disclosure is not limited thereto. In some alternative embodiments, fewer or more layers of the composite dielectric layers 410a, 410b, 410c, 410d, 410e, the conductive vias 422, and the conductive patterns 424 may be formed depending on the circuit design.

Referring to FIG. 1L, a plurality of under-bump metallurgy (UBM) patterns 500 is formed on the heat dissipation structure 400. For example, the UBM patterns 500 are formed on the composite dielectric layer 410e and the topmost conductive vias 422. In some embodiments, the UBM patterns 500 are in physical contact with the topmost conductive vias 422 to render electrical connection with the interconnect structure INT. In some embodiments, the UBM patterns 500 are formed by a sputtering process, a PVD process, a plating process, or the like. In some embodiments, the UBM patterns 500 are made of aluminum, titanium, copper, tungsten, and/or alloys thereof.

After the UBM patterns 500 are formed on the heat dissipation structure 400, a plurality of conductive terminals 600 is disposed on the UBM patterns 500. In some embodiments, the conductive terminals 600 are attached to the UBM patterns 500 through a solder flux. In some embodiments, the conductive terminals 600 are, for example, solder balls, ball grid array (BGA) balls, or controlled collapse chip connection (C4) bumps. In some embodiments, the conductive terminals 600 are made of a conductive material with low resistivity, such as Sn, Pb, Ag, Cu, Ni, Bi, or an alloy thereof.

Thereafter, a singulation process is performed on the heat dissipation structure 400, the signal transmission structure 300, and the semiconductor substrate 100 to obtain a plurality of integrated circuits 10. In some embodiments, the singulation process typically involves dicing with a rotation blade and/or a laser beam. In other words, the singulation process includes a laser cutting process, a mechanical cutting process, a laser grooving process, other suitable processes, or a combination thereof.

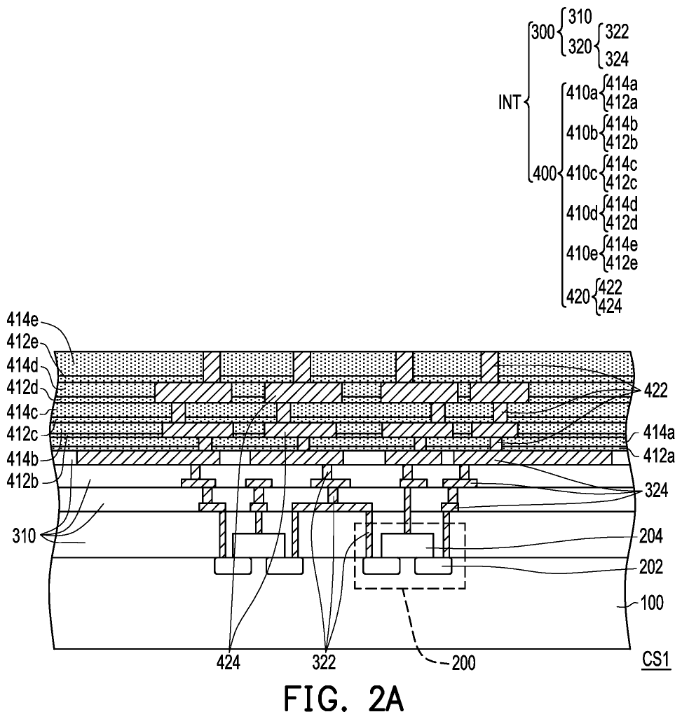

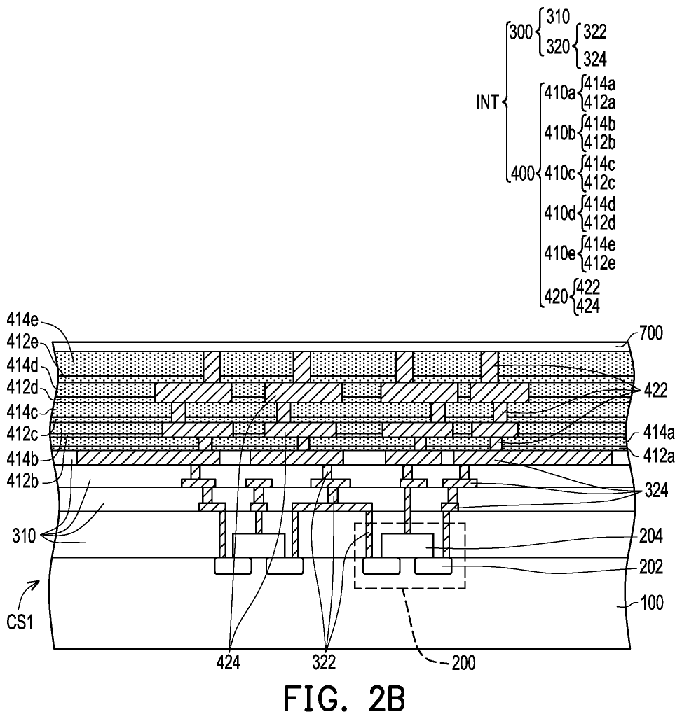

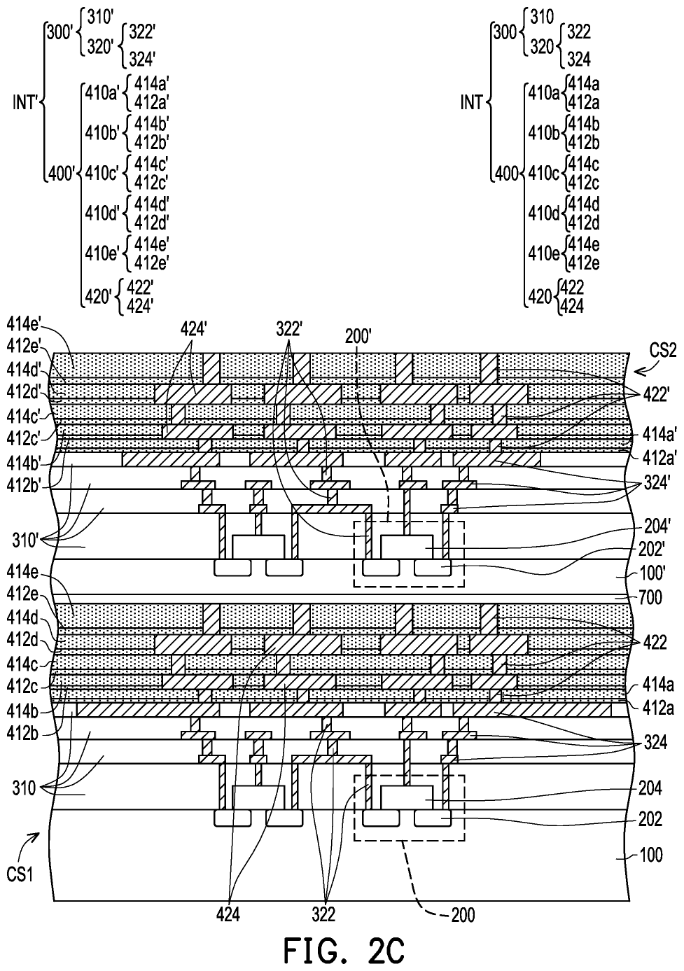

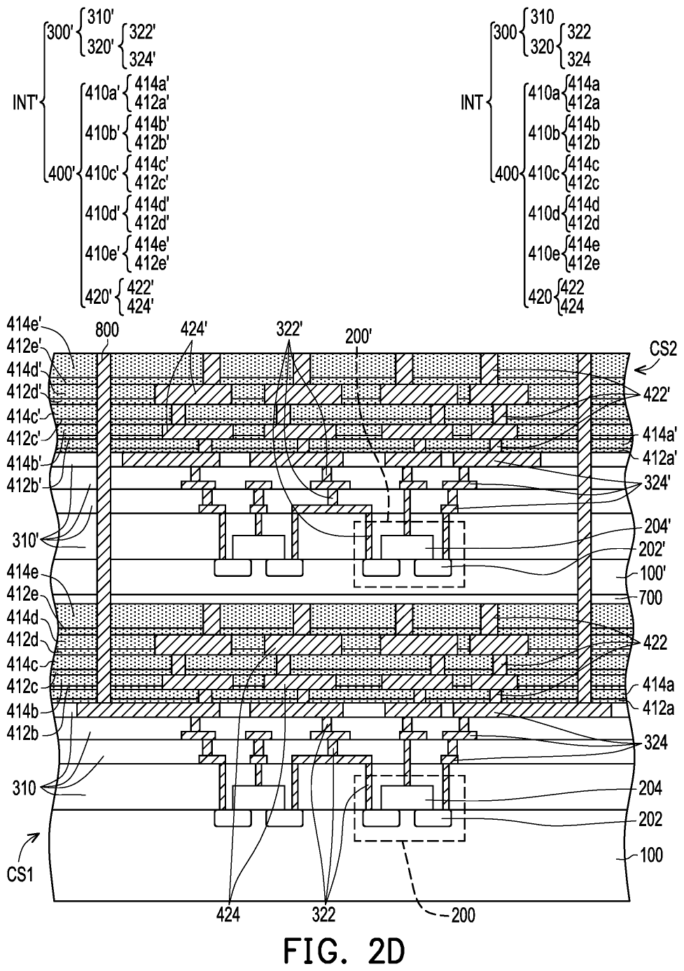

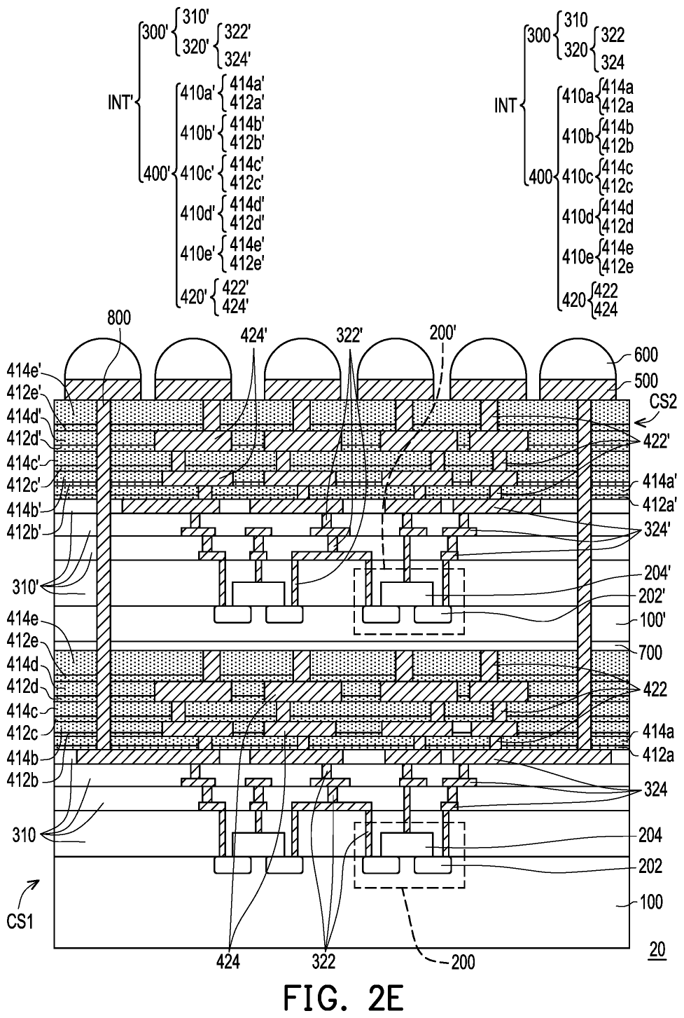

FIG. 2A to FIG. 2E are schematic cross-sectional views illustrating a manufacturing process of an integrated circuit 20 in accordance with some alternative embodiments of the disclosure. Referring to FIG. 2A, a circuit component CS1 is provided. In some embodiments, the circuit component CS1 is similar to the structure shown in FIG. 1K, so similar elements are denoted by the same reference numeral and the detailed descriptions thereof are omitted herein. In some embodiments, the circuit component CS1 is formed by performing the steps shown in FIG. 1A to FIG. 1K. It should be noted that in some embodiments, the topmost conductive vias 422 embedded in the composite dielectric layer 410e are optional and may be omitted. That is, in some embodiments, the composite dielectric layer 410e is a continuous layer without any conductive feature embedded therein.

Referring to FIG. 2B, a bonding layer 700 is formed on the circuit component CS1. For example, the bonding layer 700 is formed on the heat dissipation structure 400. In some embodiments, the bonding layer 700 is in physical contact with the topmost composite dielectric layer (i.e., the composite dielectric layer 410e) and the topmost conductive features 420 (i.e., the topmost conductive vias 422). For example, the bonding layer 700 is in physical contact with the topmost diamond layer (i.e., the diamond layer 414e) and the topmost conductive features 420 (i.e., the topmost conductive vias 422). In some embodiments, a material of the bonding layer 700 includes a metal oxide or a metal nitride. For example, the material of the bonding layer 700 includes aluminum oxide or aluminum nitride. However, the disclosure is not limited thereto. In some alternatively embodiments, other materials having adhesion properties may also be applicable as materials for the bonding layer 700. In some embodiments, the bonding layer 700 is formed by suitable fabrication techniques, such as spin-on coating, CVD, PECVD, or the like. In some embodiments, after the bonding layer 700 is formed on the circuit component CS1, a planarization process is performed on the bonding layer 700 to reduce a surface roughness thereof.

Referring to FIG. 2C, a circuit component CS2 is provided. In some embodiments, the circuit component CS2 is similar to the circuit component CS1 in FIG. 2A. In some embodiments, the circuit component CS2 includes a semiconductor substrate 100′, a plurality of transistors 200′, and an interconnect structure INT′. In some embodiments, the semiconductor substrate 100′ in the circuit component CS2 is similar to the semiconductor substrate 100 in the circuit component CS1, so the detailed description thereof is omitted herein. Each of the transistors 200′ includes source/drain regions 202′ and a gate electrode 204′. In some embodiments, the transistors 200′, the source/drain regions 202′, and the gate electrode 204′ in the circuit component CS2 are respectively similar to the transistors 200, the source/drain regions 202, and the gate electrode 204 in the circuit component CS1, so the detailed descriptions thereof are omitted herein. As illustrated in FIG. 2C, the interconnect structure INT′ includes a signal transmission structure 300′ and a heat dissipation structure 400′. The signal transmission structure 300′ includes a plurality of dielectric layers 310′ and a plurality of conductive features 320′. The conductive features 320′ include a plurality of conductive vias 322′ and a plurality of conductive patterns 324′. The conductive vias 322′ and the conductive patterns 324′ in the circuit component CS2 are respectively similar to the conductive vias 322 and the conductive patterns 324 in the circuit component CS1, so the detailed descriptions thereof are omitted herein. The heat dissipation structure 400′ includes a plurality of composite dielectric layers 410a′, 410b′, 410c′, 410d′, 410e′ and a plurality of conductive features 420′. The composite dielectric layer 410a′ includes a seed layer 412a′ and a diamond layer 414a′, the composite dielectric layer 410b′ includes a seed layer 412b′ and a diamond layer 414b′, the composite dielectric layer 410c′ includes a seed layer 412c′ and a diamond layer 414c′, the composite dielectric layer 410d′ includes a seed layer 412d′ and a diamond layer 414d′, and the composite dielectric layer 410e′ includes a seed layer 412e′ and a diamond layer 414e′. The conductive features 420′ includes a plurality of conductive vias 422′ and a plurality of conductive patterns 424′. The seed layers 412a′, 412b′, 412c′, 412d′, 412e′, the diamond layers 414a′, 414b′, 414c′, 414d′, 414e′, the conductive vias 422′, and the conductive patterns 424′ in the circuit component CS2 are respectively similar to the seed layers 412a, 412b, 412c, 412d, 412e, the diamond layers 414a, 414b, 414c, 414d, 414e, the conductive vias 422, and the conductive patterns 424 in the circuit component CS1, so the detailed descriptions thereof are omitted herein.

As illustrated in FIG. 2C, the circuit component CS2 is placed on top of the circuit component CS1 and is bonded to the circuit component CS1. In some embodiments, the circuit component CS2 is attached to the circuit component CS1 through the bonding layer 700. That is, the bonding layer 700 is sandwiched between the circuit component CS1 and the circuit component CS2. As illustrated in FIG. 2C, the bonding layer 700 is in physical contact with both the diamond layer 414e of the circuit component CS1 and the semiconductor substrate 100′ of the circuit component CS2.

In some embodiments, prior to the attachment of the circuit component CS2 and the circuit component CS1, the circuit component CS2 may be placed on a carrier substrate (not shown). Thereafter, the semiconductor substrate 100′ of the circuit component CS2 may be thinned to reduce the overall thickness of the circuit component CS2. The thinning process includes a mechanical grinding process, a CMP process, or the like. After the semiconductor substrate 100′ of the circuit component CS2 is thinned, the circuit component CS2 is placed on the bonding layer 700, so as to bond to the circuit component CS1. In some embodiments, the bonding between the circuit component CS1 and the circuit component CS2 is referred to a face-to-back bonding.

Referring to FIG. 2D, a plurality of through vias 800 is formed. In some embodiments, a material of the through vias 800 includes aluminum, titanium, copper, nickel, tungsten, or alloys thereof. The through vias 800 may be formed by electroplating, deposition, and/or photolithography and etching. As illustrated in FIG. 2D, the through vias 800 penetrate through the circuit component CS2, the bonding layer 700, the diamond layers 414e, 414d, 414c, 414b, 414a, and the seed layers 412e, 412d, 412c, 412b, 412a to be in physical contact with the topmost conductive patterns 324. In other words, the through vias 800 are electrically connected to the signal transmission structure 300 of the circuit component CS1.

Referring to FIG. 2E, a plurality of UBM patterns 500 is formed on the heat dissipation structure 400′ and the through vias 800. For example, the UBM patterns 500 are formed on the composite dielectric layer 410e′, the topmost conductive vias 422′, and the through vias 800. In some embodiments, the UBM patterns 500 in FIG. 2E are similar to the UBM patterns 500 in FIG. 1L, so the detailed descriptions thereof are omitted herein. In some embodiments, the UBM patterns 500 are in physical contact with the topmost conductive vias 422′ to render electrical connection with the interconnect structure INT′ of the circuit component CS2. Meanwhile, the UBM patterns 500 are also in physical contact with the through vias 800 to render electrical connection with the interconnect structure INT of the circuit component CS1.

As illustrated in FIG. 2E, a plurality of conductive terminals 600 is disposed on the UBM patterns 500. The conductive terminals 600 in FIG. 2E are similar to the conductive terminals 600 in FIG. 1L, so the detailed descriptions thereof are omitted herein. Thereafter, a singulation process is performed on the heat dissipation structure 400′, the signal transmission structure 300′, the semiconductor substrate 100′, the bonding layer 700, the heat dissipation structure 400, the signal transmission structure 300, and the semiconductor substrate 100 to obtain a plurality of integrated circuits 20. In some embodiments, the singulation process typically involves dicing with a rotation blade and/or a laser beam. In other words, the singulation process includes a laser cutting process, a mechanical cutting process, a laser grooving process, other suitable processes, or a combination thereof.

In some embodiments, the composite dielectric layers 410a, 410a′, 410b, 410b′, 410c, 410c′, 410d, 410d′, 410e, and 410e′ may be formed on the signal transmission structures 300 and 300′ through steps similar to the steps shown in FIG. 1D to FIG. 1E. As such, by first depositing the seed layers (i.e., the seed layers 412a, 412a′, 412b, 412b′, 412c, 412c′, 412d, 412d′, 412e, and 412e′) on the signal transmission structures 300, 300′ and subsequently growing the diamond layers (i.e., the diamond layers 414a, 414a′, 414b, 414b′, 414c, 414c′, 414d, 414d′, 414e, and 414e′) on the seed layers, the diamond layers can be integrated into the integrated circuit 20 while being compatible with the BEOL thermal budget. Moreover, with the integration of the heat dissipation layers (i.e., the diamond layers 414a, 414a′, 414b, 414b′, 414c, 414c′, 414d, 414d′, 414e, and 414e′), the performance and the lifetime of the integrated circuit 20 may be sufficiently improved.

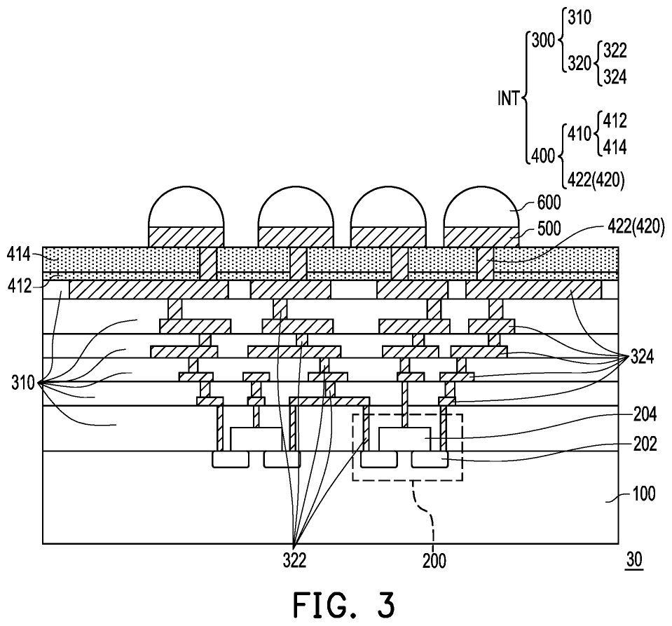

FIG. 3 is a schematic cross-sectional view of an integrated circuit 30 in accordance with some alternative embodiments of the disclosure. Referring to FIG. 3, the integrated circuit 30 in FIG. 3 is similar to the integrated circuit 10 in FIG. 1L, so similar elements are denoted by the same reference numeral and the detailed descriptions thereof are omitted herein. The difference between the integrated circuit 30 in FIG. 3 and the integrated circuit 10 in FIG. 1L is that the heat dissipation structure 400 in the integrated circuit 30 of FIG. 3 only includes one composite dielectric layer 410. Moreover, the conductive features 420 of the heat dissipation structure 400 only includes conductive vias 422. In some embodiments, the composite dielectric layer 410 includes a seed layer 412 and a diamond layer 414 disposed on the seed layer 412. The seed layer 412 and the diamond layer 414 in FIG. 3 are respectively similar to the seed layer 412a and the diamond layer 414a in FIG. 1E, so the detailed descriptions thereof are omitted herein. Meanwhile, the conductive vias 422 in FIG. 3 are similar to the conductive vias 422 in FIG. 1G, so the detailed descriptions thereof are omitted herein.

In some embodiments, the composite dielectric layer 410 may be formed on the signal transmission structure 300 through steps similar to the steps shown in FIG. 1D to FIG. 1E. As such, by first depositing the seed layer 412 on the signal transmission structure 300 and subsequently growing the diamond layer 414 on the seed layer 412, the diamond layer 414 can be integrated into the integrated circuit 30 while being compatible with the BEOL thermal budget. Moreover, with the integration of the heat dissipation layer (i.e., the diamond layer 414), the performance and the lifetime of the integrated circuit 30 may be sufficiently improved.

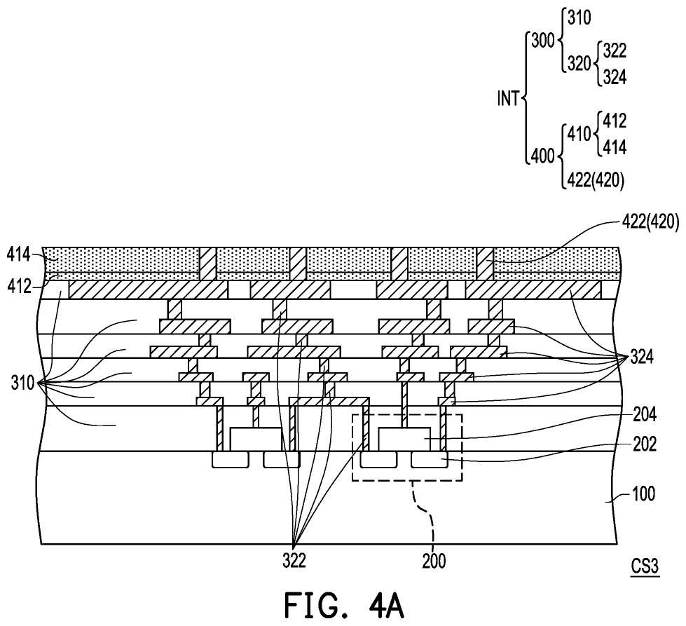

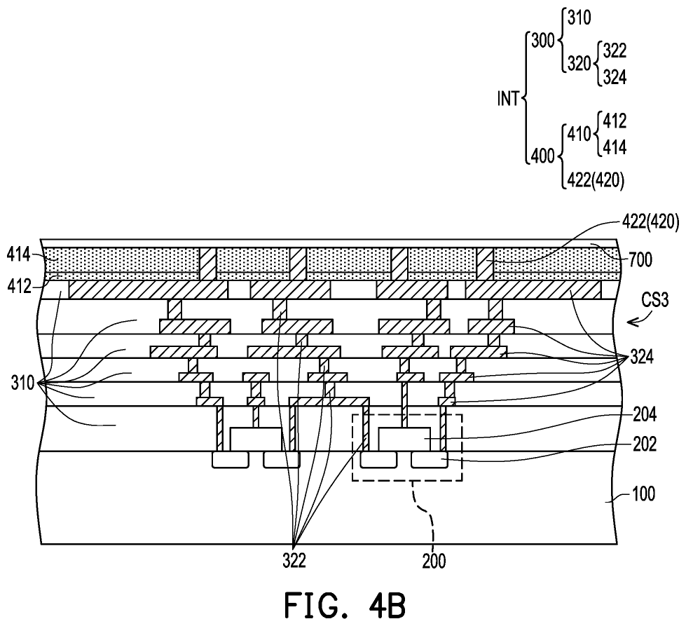

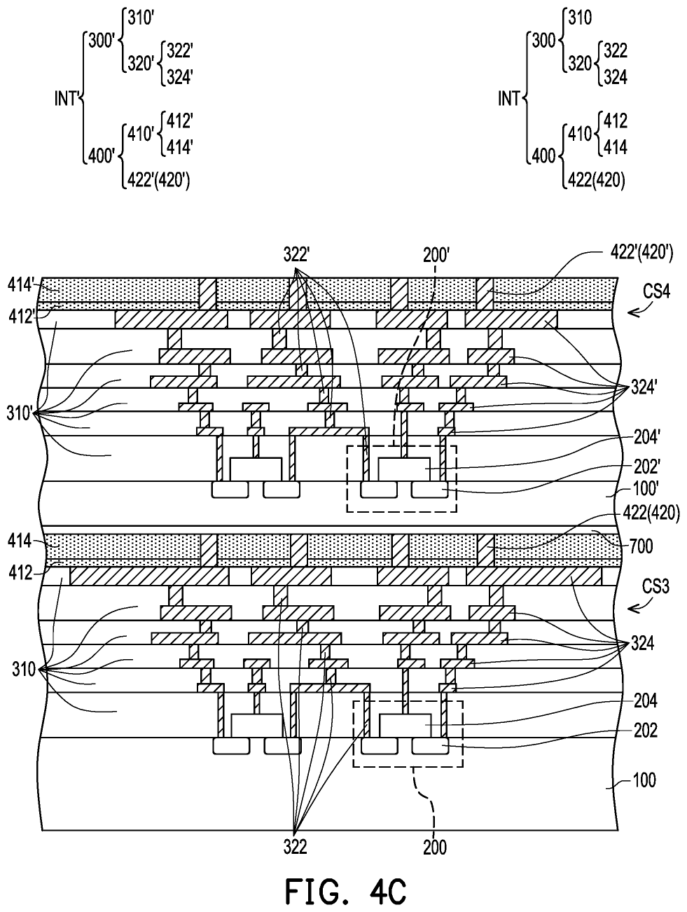

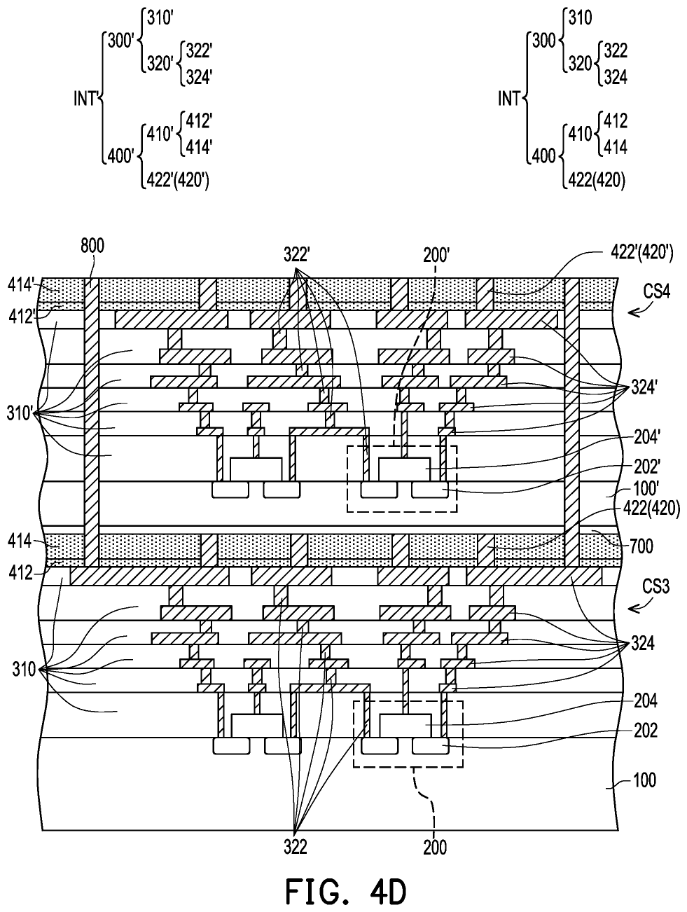

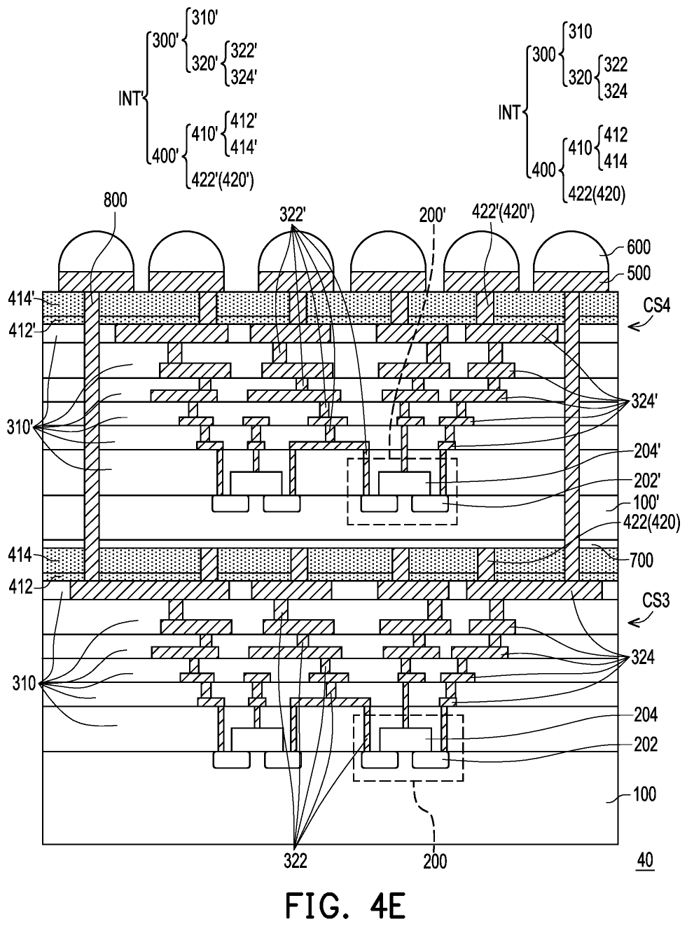

FIG. 4A to FIG. 4E are schematic cross-sectional views illustrating a manufacturing process of an integrated circuit 40 in accordance with some alternative embodiments of the disclosure. Referring to FIG. 4A, a circuit component CS3 is provided. In some embodiments, the circuit component CS3 is similar to the integrated circuit 30 shown in FIG. 3, so similar elements are denoted by the same reference numeral and the detailed descriptions thereof are omitted herein. However, the UBM patterns 500 and the conductive terminals 600 in the integrated circuit 30 of FIG. 3 are omitted in the circuit component CS3 in FIG. 4A. It should be noted that in some embodiments, the conductive vias 422 embedded in the composite dielectric layer 410 are optional and may be omitted. That is, in some embodiments, the composite dielectric layer 410 is a continuous layer without any conductive feature embedded therein.

Referring to FIG. 4B, a bonding layer 700 is formed on the circuit component CS3. For example, the bonding layer 700 is formed on the heat dissipation structure 400. In some embodiments, the bonding layer 700 in FIG. 4B is similar to the bonding layer 700 in FIG. 2B, so the detailed description thereof is omitted herein. In some embodiments, the bonding layer 700 is in physical contact with the composite dielectric layer 410 and the conductive features 420 (i.e., the conductive vias 422). For example, the bonding layer 700 is in physical contact with the diamond layer 414 and the conductive vias 422. In some embodiments, after the bonding layer 700 is formed on the circuit component CS3, a planarization process is performed on the bonding layer 700 to reduce a surface roughness thereof.

Referring to FIG. 4C, a circuit component CS4 is provided. In some embodiments, the circuit component CS4 is similar to the circuit component CS3 in FIG. 4A. In some embodiments, the circuit component CS4 includes a semiconductor substrate 100′, a plurality of transistors 200′, and an interconnect structure INT′. In some embodiments, the semiconductor substrate 100′ in the circuit component CS4 is similar to the semiconductor substrate 100 in the circuit component CS3, so the detailed description thereof is omitted herein. Each of the transistors 200′ includes source/drain regions 202′ and a gate electrode 204′. In some embodiments, the transistors 200′, the source/drain regions 202′, and the gate electrode 204′ in the circuit component CS4 are respectively similar to the transistors 200, the source/drain regions 202, and the gate electrode 204 in the circuit component CS3, so the detailed descriptions thereof are omitted herein. As illustrated in FIG. 4C, the interconnect structure INT′ includes a signal transmission structure 300′ and a heat dissipation structure 400′. The signal transmission structure 300′ includes a plurality of dielectric layers 310′ and a plurality of conductive features 320′. The conductive features 320′ include a plurality of conductive vias 322′ and a plurality of conductive patterns 324′. The conductive vias 322′ and the conductive patterns 324′ in the circuit component CS4 are respectively similar to the conductive vias 322 and the conductive patterns 324 in the circuit component CS3, so the detailed descriptions thereof are omitted herein. The heat dissipation structure 400′ includes a composite dielectric layer 410′ and a plurality of conductive features 420′. The composite dielectric layer 410′ includes a seed layer 412′ and a diamond layer 414′. The conductive features 420′ includes a plurality of conductive vias 422′. The seed layer 412′, the diamond layer 414′, and the conductive vias 422′ in the circuit component CS4 are respectively similar to the seed layer 412, the diamond layer 414, and the conductive vias 422 in the circuit component CS3, so the detailed descriptions thereof are omitted herein.

As illustrated in FIG. 4C, the circuit component CS4 is placed on top of the circuit component CS3 and is bonded to the circuit component CS3. In some embodiments, the circuit component CS4 is attached to the circuit component CS3 through the bonding layer 700. That is, the bonding layer 700 is sandwiched between the circuit component CS3 and the circuit component CS4. As illustrated in FIG. 4C, the bonding layer 700 is in physical contact with both the diamond layer 414 of the circuit component CS3 and the semiconductor substrate 100′ of the circuit component CS4.

In some embodiments, prior to the attachment of the circuit component CS4 and the circuit component CS3, the circuit component CS4 may be placed on a carrier substrate (not shown). Thereafter, the semiconductor substrate 100′ of the circuit component CS4 may be thinned to reduce the overall thickness of the circuit component CS4. The thinning process includes a mechanical grinding process, a CMP process, or the like. After the semiconductor substrate 100′ of the circuit component CS4 is thinned, the circuit component CS4 is placed on the bonding layer 700, so as to bond to the circuit component CS3. In some embodiments, the bonding between the circuit component CS4 and the circuit component CS3 is referred to a face-to-back bonding.

Referring to FIG. 4D, a plurality of through vias 800 is formed. In some embodiments, the through vias 800 in FIG. 4D are similar to the through vias 800 in FIG. 2D, so the detailed descriptions thereof are omitted herein. As illustrated in FIG. 4D, the through vias 800 penetrate through the circuit component CS4, the bonding layer 700, the diamond layer 414, and the seed layer 412 to be in physical contact with the topmost conductive patterns 324. In other words, the through vias 800 are electrically connected to the signal transmission structure 300 of the circuit component CS3.

Referring to FIG. 4E, a plurality of UBM patterns 500 is formed on the heat dissipation structure 400′ and the through vias 800. For example, the UBM patterns 500 are formed on the composite dielectric layer 410′, the conductive vias 422′, and the through vias 800. In some embodiments, the UBM patterns 500 in FIG. 4E are similar to the UBM patterns 500 in FIG. 2E, so the detailed descriptions thereof are omitted herein. In some embodiments, the UBM patterns 500 are in physical contact with the conductive vias 422′ to render electrical connection with the interconnect structure INT′ of the circuit component CS4. Meanwhile, the UBM patterns 500 are also in physical contact with the through vias 800 to render electrical connection with the interconnect structure INT of the circuit component CS3.

As illustrated in FIG. 4E, a plurality of conductive terminals 600 is disposed on the UBM patterns 500. The conductive terminals 600 in FIG. 4E are similar to the conductive terminals 600 in FIG. 2E, so the detailed descriptions thereof are omitted herein. Thereafter, a singulation process is performed on the heat dissipation structure 400′, the signal transmission structure 300′, the semiconductor substrate 100′, the bonding layer 700, the heat dissipation structure 400, the signal transmission structure 300, and the semiconductor substrate 100 to obtain a plurality of integrated circuits 40. In some embodiments, the singulation process typically involves dicing with a rotation blade and/or a laser beam. In other words, the singulation process includes a laser cutting process, a mechanical cutting process, a laser grooving process, other suitable processes, or a combination thereof.

In some embodiments, the composite dielectric layers 410 and 410′ may be formed on the signal transmission structures 300 and 300′ through steps similar to the steps shown in FIG. 1D to FIG. 1E. As such, by first depositing the seed layers (i.e., the seed layers 412 and 412′) on the signal transmission structures 300, 300′ and subsequently growing the diamond layers (i.e., the diamond layers 414 and 414′) on the seed layers, the diamond layers can be integrated into the integrated circuit 40 while being compatible with the BEOL thermal budget. Moreover, with the integration of the heat dissipation layer (i.e., the diamond layers 414 and 414′), the performance and the lifetime of the integrated circuit 40 may be sufficiently improved.

In accordance with some embodiments of the disclosure, an integrated circuit includes a semiconductor substrate and an interconnect structure. The interconnect structure is disposed on the semiconductor substrate. The interconnect structure includes a signal transmission structure and a heat dissipation structure. The heat dissipation structure is disposed on the signal transmission structure and includes composite dielectric layers and first conductive features. Each of the composite dielectric layers includes a seed layer and a heat dissipation layer disposed on the seed layer. The first conductive features are embedded in the composite dielectric layers.

In accordance with some alternative embodiments of the disclosure, an integrated circuit includes a first circuit component, a second circuit component, a bonding layer, and through vias. The first circuit component includes a first semiconductor substrate and a first interconnect structure disposed on the first semiconductor substrate. The first interconnect structure includes first dielectric layers, first seed layers, and first diamond layers. The first dielectric layers are stacked on one another. The first seed layers and the first diamond layers are alternately stacked on one another above the first dielectric layers. The second circuit component includes a second semiconductor substrate and a second interconnect structure disposed on the second semiconductor substrate. The second interconnect structure includes second dielectric layers, second seed layers, and second diamond layers. The second dielectric layers are stacked on one another. The second seed layer and the second diamond layers are alternately stacked on one another above the second dielectric layers. The bonding layer is sandwiched between the first circuit component and the second circuit component. The through vias penetrate through the second circuit component, the bonding layer, the first seed layer, and the first diamond layers.

In accordance with some embodiments of the disclosure, a manufacturing method of an integrated circuit includes at least the following steps. A semiconductor substrate is provided. An interconnect structure is formed on the semiconductor substrate. The interconnect structure is formed by at least the following steps. A signal transmission structure is formed on the semiconductor substrate. A heat dissipation structure is formed on the signal transmission structure. The heat dissipation structure is formed by at least the following steps. A seed layer is deposited on the signal transmission structure. A diamond layer is grown on the seed layer. First conductive features are formed in the seed layer and the diamond layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit, comprising:
a semiconductor substrate; and
an interconnect structure disposed on the semiconductor substrate, comprising:
a signal transmission structure; and
a heat dissipation structure disposed on the signal transmission structure, comprising:
composite dielectric layers, wherein each of the composite dielectric layers comprises a seed layer and a heat dissipation layer disposed on the seed layer; and
first conductive features embedded in the composite dielectric layers.

2. The integrated circuit of claim 1, wherein the signal transmission structure comprises:
dielectric layers, wherein a material of the dielectric layers is different from a material of the seed layers and a material of the heat dissipation layers; and
second conductive features embedded in the dielectric layers.

3. The integrated circuit of claim 2, wherein the material of the seed layers comprises cubic boron nitride and the material of the heat dissipation layers comprises diamond.

4. The integrated circuit of claim 2, further comprising transistors disposed on the semiconductor substrate, wherein the first conductive features are electrically connected to the transistors through the second conductive features.

5. The integrated circuit of claim 2, wherein a bottommost first conductive feature is in physical contact with a topmost second conductive feature.

6. The integrated circuit of claim 2, wherein a topmost dielectric layer is in physical contact with a bottommost seed layer.

7. The integrated circuit of claim 2, wherein a number of the dielectric layers is four or more.

8. The integrated circuit of claim 1, wherein a top surface of each of the heat dissipation layers is coplanar with a top surface of the corresponding first conductive feature.

9. The integrated circuit of claim 1, wherein the first conductive features comprise:
conductive patterns extending horizontally; and
conductive vias extending vertically to connect the conductive patterns located at different level heights, wherein each of the conductive patterns penetrates through one of the composite dielectric layers while each of the conductive vias penetrates through another one of the composite dielectric layers.

10. An integrated circuit, comprising:
a first circuit component, comprising:
a first semiconductor substrate; and
a first interconnect structure disposed on the first semiconductor substrate, comprising:
first dielectric layers stacked on one another; and
first seed layers and first diamond layers alternately stacked on one another above the first dielectric layers;
a second circuit component, comprising
a second semiconductor substrate; and
a second interconnect structure disposed on the second semiconductor substrate, comprising:
second dielectric layers stacked on one another; and
second seed layers and second diamond layers alternately stacked on one another above the second dielectric layers;
a bonding layer sandwiched between the first circuit component and the second circuit component; and
through vias penetrating through the second circuit component, the bonding layer, the first seed layers, and the first diamond layers.

11. The integrated circuit of claim 10, wherein the first circuit component further comprises:
first conductive patterns and first conductive vias embedded in the first dielectric layers; and
second conductive patterns and second conductive vias embedded in the first seed layers and the first diamond layers, wherein the first conductive patterns, the first conductive vias, the second conductive patterns, and the second conductive vias are electrically connected to one another.

12. The integrated circuit of claim 11, wherein the through vias are in physical contact with a topmost first conductive pattern.

13. The integrated circuit of claim 10, wherein a material of the first dielectric layers is different from a material of the first seed layers.

14. The integrated circuit of claim 13, wherein the material of the first seed layers comprises cubic boron nitride.

15. The integrated circuit of claim 10, wherein the bonding layer is in physical contact with the second semiconductor substrate and a topmost first diamond layer.

16. A manufacturing method of an integrated circuit, comprising:
providing a semiconductor substrate; and
forming an interconnect structure on the semiconductor substrate, comprising:
forming a signal transmission structure on the semiconductor substrate; and
forming a heat dissipation structure on the signal transmission structure, comprising:
depositing a seed layer on the signal transmission structure;
growing a diamond layer on the seed layer; and
forming first conductive features in the seed layer and the diamond layer.

17. The method of claim 16, wherein the seed layer is formed of cubic boron nitride.

18. The method of claim 16, wherein forming the first conductive features in the seed layer and the diamond layer comprises:
patterning the diamond layer and the seed layer to form openings in the diamond layer and the seed layer; and
depositing a conductive material in the openings to form the first conductive features.

19. The method of claim 18, wherein top surfaces of the first conductive features are formed to be coplanar with a top surface of the diamond layer.

20. The method of claim 16, wherein forming the signal transmission structure comprises:
forming dielectric layers on the semiconductor substrate; and
forming second conductive features in the dielectric layers, wherein the first conductive features are electrically connected to the second conductive features.
